(19) United States
(12) Patent Application Publication
(10) Pub. No.: US 2013/0094143 A1
(43) Pub. Date: Apr. 18, 2013

(54) COOLING SYSTEM FOR ELECTRONIC DEVICE AND ELECTRONIC DEVICE HAVING SAME

(71) Applicant: TAI-WEI LIN, Tu-Cheng (TW)

(72) Inventor: TAI-WEI LIN, Tu-Cheng (TW)

(73) Assignee: HON HAI PRECISION INDUSTRY CO., LTD., Tu-Cheng (TW)

(21) Appl. No.: 13/403,525

(22) Filed: Feb. 23, 2012

(30) Foreign Application Priority Data
Oct. 12, 2011 (TW) 100136985

(51) Int. Cl. H05K 7/20

(52) U.S. Cl. 361/692

(57) ABSTRACT

An electronic device includes a plurality of electronic components and a cooling system. The cooling system includes a chassis defining an airflow channel including an air inlet and an opposing air outlet, a fan assembly including a plurality of fans located at the air outlet, a valve assembly including a plurality of valve plates located at the air inlet, and a control unit controlling the operation of the fan assembly and of the valve assembly. When only some of the electronic components are operated, the operated electronic components send a signal to the control unit, the control unit calculates the particular valve plates and fans which need to be activated, and activates or starts only the relevant and required valve plates and fans to cool the electronic components.

### BACKGROUND

1. Technical Field

The disclosure generally relates to cooling systems for electronic devices.

2. Description of Related Art

The many electronic components in an electronic device generate heat when operating. In designing an electronic device, cooling systems are used to dissipate heat generated by the electronic components to prevent the electronic components from overheating.

Many cooling systems include an air conducting cover defining a plurality of airflow channels, a number of fans equal to the number of airflow channels and electronic components mounted in the airflow channels. The fans are configured to draw air into the airflow channels and force air past the electronic components which are cooled accordingly. However, if there is no electronic component in some of airflow channels and all of the fans are still operating, as a result, the power consumed will be inordinate and to some extent wasted.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary cooling system and electronic device having the cooling system. Moreover, in the drawings, like reference numerals designate corresponding parts throughout the several views. Wherever possible, the same reference numbers are used throughout the drawings to refer to the same or like elements of an embodiment.

FIG. 1 is a schematic view of an embodiment of a cooling system, and an electronic device.

FIG. 2 is schematic view of the cooling system in FIG. 1 seen from another aspect.

FIG. 3 is a diagram of the electronic device in FIG. 1.

### DETAILED DESCRIPTION

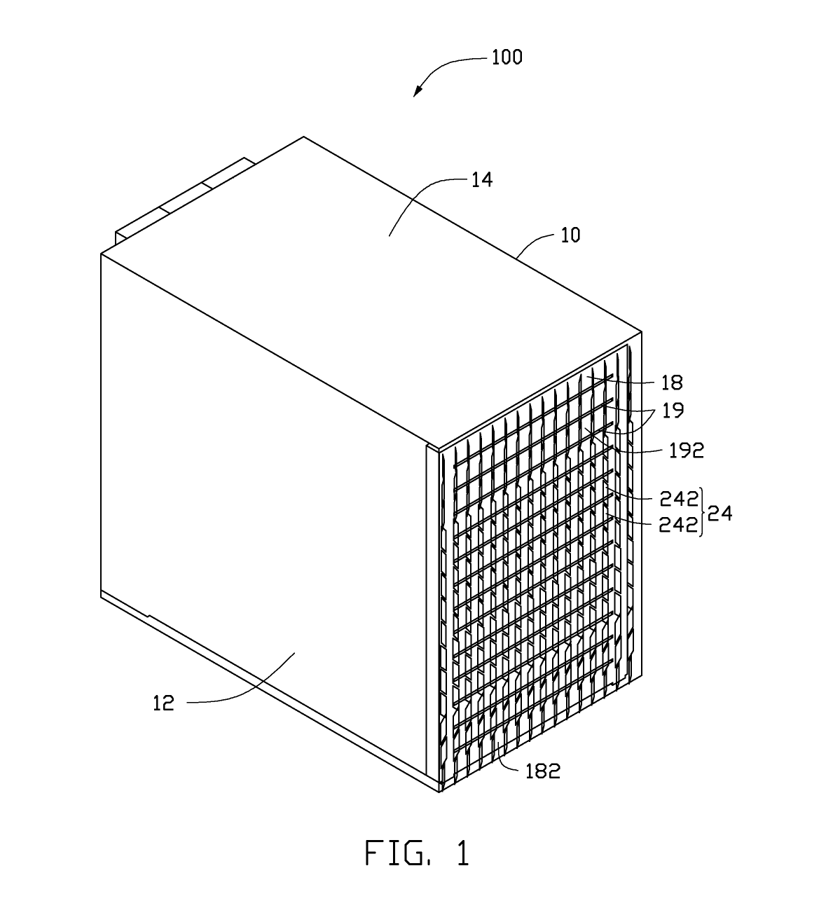

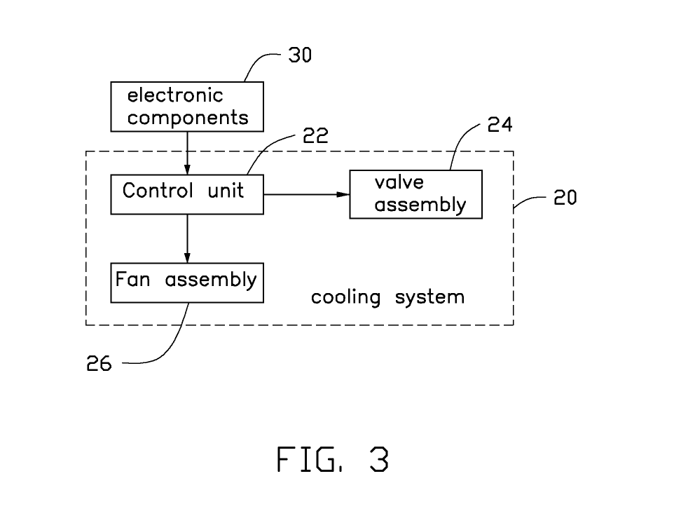

Referring to FIG. 1 and FIG. 3, an electronic device 100 includes a chassis 10, a cooling system 20 and a plurality of electronic components 30. The cooling system 20 and the electronic components 30 are both mounted to the chassis 10.

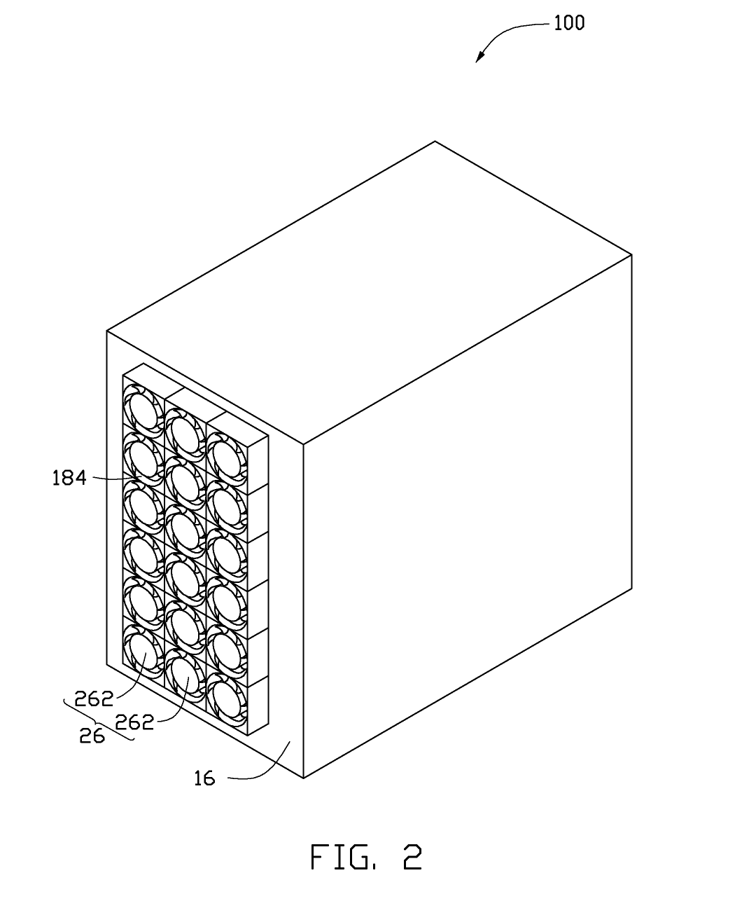

Referring to FIG. 2, the chassis 10 includes two opposite sidewalls 12, and two opposite main boards 14 connecting the sidewalls 12, and an end wall 16 connecting the sidewalls 12 with the main boards 14. The sidewalls 12 and the main boards 14 enclose an airflow channel 18. The chassis 10 further includes an air inlet 182 and an air outlet 184, each located at an opposite end of the airflow channel 18 and communicating with the airflow channel 18. In this exemplary embodiment, the air outlet 184 is formed in the end wall 16.

The chassis 10 may further include a plurality of spaced partition boards 19 extending substantially the length of the chassis 10 from the air inlet 182 to the air outlet 184 and located in the airflow channel 18, which divide the airflow channel 18 into a plurality of sub-channels 192, i.e., every two adjacent partition boards 19 form a sub-channel 192 between them. The sub-channels 192 accommodate the electronic components 30.

The cooling system 20 includes a control unit 22, a valve assembly 24 and a fan assembly 26. The control unit 22 controls the operation of the valve assembly 24 and the fan assembly 26. The valve assembly 24 includes a plurality of valve plates 242 fixed at the air inlet 182 and each is aligned with a sub-channel 192. The fan assembly 26 includes a plurality of fans 262 fixed at the air outlet 184.

Referring to FIGS. 3 and 4, when some of the electronic components 30 are operating, the operating electronic components 30 send a signal to the control unit 22. The control unit 22 calculates the particular valve plates 242 and corresponding fans 262 which are relevant to, and required to cool, the operated electronic components 30 according to the signals from the operated electronic components 30. Then, the control unit 22 activates the required valve plate(s) 242 to open, and the corresponding fan(s) 262 to work, to cool the operated electronic components 30. Thus, if only some of the electronic components 30 are operating or being used, only the relevant and required valve plates 242 are opened and only the corresponding fans 262 are started out of all the fans 262. As a result, the power supplied to the electronic device can be reduced and the power supplied more efficiently, due to the presence of the control unit 22. For further illustration of the operation of the cooling system 20, another example is provided below: if only the electronic components 30 located in one of the sub-channels 192 need to be functioning, the control unit 22 only opens the valve plate(s) 242 which serves that particular sub-channel 192 and activates the fan(s) 262 corresponding to that sub-channel 192, but the other valve plates 242 and fans 262 are left closed and shut down, so as to cool only the operated electronic components 30 which need cooling.

It is to be understood, however, that even through numerous characteristics and advantages of the disclosure have been set forth in the foregoing description, together with details of the system and function of the disclosure, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A cooling system, comprising:
a chassis defining an airflow channel including an air inlet and an opposite air outlet, the chassis for containing an electronic device;
a fan assembly including a plurality of fans, the fan assembly located at the air outlet;
a valve assembly including a plurality of valve plates, the valve assembly located at the air inlet;
a control unit in electronic communication with the electronic device and for controlling an operation of the fan assembly and the valve assembly in response to a signal from the electronic device indicating the electronic device is in use.

2. The cooling system as claimed in claim 1, wherein the chassis includes two opposite sidewalls, and two opposite main boards respectively connecting the sidewalls; the sidewalls and the main boards cooperatively enclose the airflow channel.

3. The cooling system as claimed in claim 2, wherein the chassis further includes a plurality of spaced partition boards located in the airflow channel, dividing the airflow channel into a plurality of sub-channels.

4. An electronic device, comprising:
a cooling system comprising:
a chassis defining an airflow channel including an air inlet and an opposite air outlet, the chassis for containing an electronic device;
a fan assembly including a plurality of fans, the fan assembly located at the air outlet;
a valve assembly including a plurality of valve plates, the valve assembly located at the air inlet;
a control unit in electronic communication with the electronic device and for controlling an operation of the fan assembly and the valve assembly in response to a signal from the electronic device indicating the electronic device is in use.

5. The electronic device as claimed in claim 4, wherein the chassis includes two opposite sidewalls, and two opposite main boards respectively connecting the sidewalls; the sidewalls and the main boards cooperatively enclose the airflow channel.

6. The electronic device as claimed in claim 5, wherein the chassis further include a plurality of spaced partition boards located in the airflow channel, dividing the airflow channel into a plurality of sub-channels.

7. An electronic device, comprising:
a plurality of electronic components; and
a cooling system comprising:
a chassis defining an airflow channel including an air inlet and an opposite air outlet;
a fan assembly including a plurality of fans, the fan assembly located at the air outlet;
a valve assembly including a plurality of valve plates, the valve assembly located at the air inlet;
a control unit controlling an operation of the fan assembly and the valve assembly;
wherein when some of the electronic components are operated, the operated electronic components send a signal to the control unit, the control unit calculates the amount of valve plates and fans, which are required to start to cool the operated electronic components according to the signal from the operated electronic components, the control unit then only starts the required valve plates and fans to cool the operated electronic components.

8. The electronic device as claimed in claim 7, wherein the chassis includes two opposite sidewalls, and two opposite main boards respectively connecting the sidewalls; the sidewalls and the main boards cooperatively enclose the airflow channel.

9. The electronic device as claimed in claim 8, wherein the chassis further includes a plurality of spaced partition boards located in the airflow channel, dividing the airflow channel into a plurality of sub-channels.

10. The electronic device as claimed in claim 9, wherein if the electronic components only located in one of the sub-channels need to be operated, the control unit only starts valve plates and fans corresponding to the one of the sub-channels to cool the operated electronic components in the one of the sub-channels.
